(19) United States
(12) Patent Application Publication
(10) Pub. No.: US 2024/0328960 A1
(43) Pub. Date: Oct. 3, 2024

(54) Method and Apparatus for Optimizing a Measurement Pattern on a Wafer

(71) Applicant: Robert Bosch GmbH, Stuttgart (DE)

(72) Inventor: Peter Ebersbach, Radebeul (DE)

(21) Appl. No.: 18/608,169

(22) Filed: Mar. 18, 2024

(30) Foreign Application Priority Data
Mar. 31, 2023 (DE) 10 2023 203 019.5

(51) Int. Cl. G01N 21/95

(52) U.S. Cl. CPC G01N 21/9501; G01N 2201/126

(57) ABSTRACT

A method for optimizing a measurement pattern of measurement points for a semiconductor wafer includes (i) obtaining a plurality of measured values with associated measurement points and timestamps, (ii) partitioning the semiconductor wafer into zones, wherein the zones are characterized in that measured values whose measurement positions are within the respective zone have the same characteristic, (iii) determining a variation of the measured values for each of the zones along a predetermined time period, the timestamps of which are within the predetermined time window, and (iv) defining the measurement pattern, wherein, depending on the variations, a measurement point density is defined for each of the zones, in particular a higher measurement point density is selected in the zones with higher variation along the time.

This application claims priority under 35 U.S.C. § 119 to patent application no. DE 10 2023 203 019.5, filed on Mar. 31, 2023 in Germany, the disclosure of which is incorporated herein by reference in its entirety.

The disclosure relates to a method for optimizing a measurement pattern of measurement points for a semiconductor wafer as well as an apparatus, a computer program and a machine readable storage medium.

### BACKGROUND

Methods are known for determining optimal positions of measurement points on the semiconductor wafer, for example, in order to measure the processed wafer with limited measuring resources as extensively and precisely as possible (semiconductor wafer sampling plan optimization).

Measurement data often does not have the resolution and thus the sensitivity to follow process variations with better accuracy and validity. Interpolations and in particular extrapolations must always be considered with error considerations in the application.

Thus, an object of the disclosure is to provide a method for determining measurement point positions on the wafer that can capture as accurately and reliably as possible a process result of the processed wafer with respect to process variations.

### SUMMARY

In a first aspect, the disclosure relates to a computer-implemented method for optimizing a measurement pattern of measurement points for a semiconductor wafer.

The method begins with obtaining a plurality of measured values and their associated measurement points and associated timestamps. That is to say, for each measured value, there is a measurement point, which characterizes at which position the measured value was detected on the wafer, e.g. based on a coordinate. Furthermore, a timestamp is available for each measured value, which indicates a time at which the corresponding measurement was taken. It should be noted that the measured values were preferably acquired with the same or identical measurement instrument but on different wafers, in particular from the same batch.

Subsequently, the semiconductor wafer is partitioned into a plurality of zones, wherein measured values whose measurement positions lie within the respective zone have substantially the same characteristic, for example, with regard to a distribution of the measured values. A zone can be understood to mean a limited spatial area on the wafer surface. The partitioning may be done by plotting the measured values on a radius of the wafer, wherein the radius is divided into a plurality of zones/sections depending on variations of the measured values.

This is followed by a determination of a variation or fluctuation of those measured values for each of the zones along a predetermined time period whose timestamps are within a predetermined time window.

This is followed by a definition of the measurement pattern, wherein, depending on the variations, a measurement point density is defined for each of the zones, in particular a higher measurement point density is selected in the zones with higher variation along the time. Preferably, the zone with the highest variation obtains the highest measurement point density, wherein the further zones obtain a lower measurement point density depending on their variation in descending order.

A specific positioning of the measurement points within the zones can be carried out by means of known methods. Optionally, the defined measurement pattern can be used, i.e., a freshly processed wafer is measured according to the measurement pattern.

It is proposed that a predetermined maximum number of measurement points is given that is distributed on the wafer according to the measurement pattern.

Furthermore, it is proposed that the zones of a surface portion of the semiconductor wafer are allocated and preferably the surface portions are in the shape of a circle, rectangle, or ellipse.

In further aspects, the disclosure relates to an apparatus and to a computer program, which are each configured to perform the aforementioned methods, and to a machine-readable storage medium on which said computer program is stored.

### BRIEF DESCRIPTION OF THE DRAWINGS

Embodiments of the disclosure are explained in greater detail below with reference to the accompanying drawings. The drawings show:

FIG. 1 schematic measurements of a parameter P on a wafer as well as measurement positions on the wafer; and

FIG. 2 schematically shows an exemplary embodiment of a method for optimizing the measurement positions.

### DETAILED DESCRIPTION

It is assumed that at least one wafer, preferably a batch of wafers according to a formulation, has been processed. For example, the wafers are flushed with a gas or the like. The wafer is then thoroughly measured so that precise measurement information is available over the entire wafer, in particular in a finely granular manner.

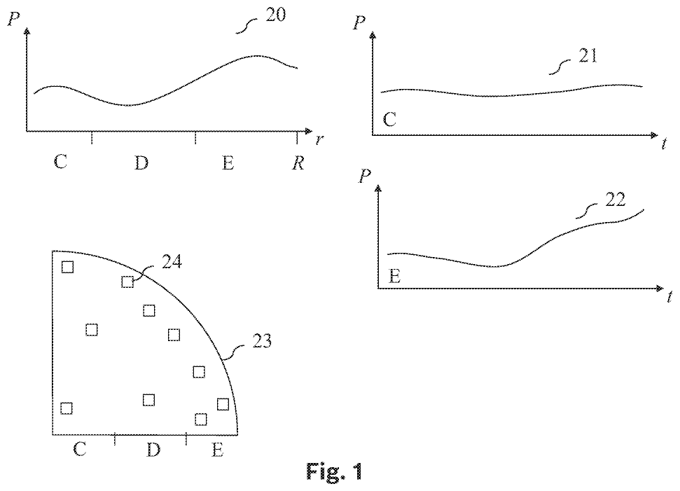

The measurement along a radius r of the wafer is then considered in more detail, see FIG. 1, reference numeral 20. On the x-axis, the radius r of the wafer is plotted up to the maximum value of the radius R. R can, for example, be 150 mm. On the y-axis, the value of the parameter P (e.g., layer thickness; line width; resistance; etc.) is plotted. It can be seen from diagram 20 that at the edge of the wafer, parameter P has a stronger variation compared to the interior of the wafer.

Depending on a magnitude of the variation of the parameter, the radius is divided into different zones (C,D,E) having a similar variation of the parameter P. This partitioning can be referred to as radial surface determination and can be achieved by partitioning a wafer surface into radially equal distances or the distances corresponding to equal surface contents. Advantageously, 3-5 surfaces are to be applied according to the process chamber characteristic. Radial zones of up to 9 surfaces are also conceivable, for example for CMP (mechanical polishing).

After the zones have been defined, a variation of the parameter over time is preferably considered. This is shown in FIG. 1 with reference numerals 21 and 22. For each of the zones C,D,E, a plot of the parameter over time, or implicitly over the order of the processed wafers, is made if these were processed sequentially. As can be seen from diagram 21, which plots the parameter P for zone C over time t, the parameter P behaves stably over time t for zones C. It is conceivable that the parameter t is also stable for zone D. For zone E, it can be observed that the parameter drifts over time, as can be seen with reference numeral 22.

Based on the drift, it can be concluded that it is makes sense it terms of process technology to provide this area with a higher measurement point density in order to obtain a reliable image of the current state of the wafer. As shown schematically in FIG. 1 by a quadrant 23 of a wafer, based on the stable behavior of parameter P in zone C and D, a few measurement points 24 are evenly distributed within these zones. Based on the drift, more measurement points 24 are defined in zone E, i.e. the measurement point density is higher in zone E than in the other zones.

In summary, it can be said that the measurement process histories are analyzed with regard to scattering/variations: once along the wafer and a second time along a time axis. Finally, the area of the wafer with large fluctuations is selected. More measurement points are used in this area than in the other areas. The measurement points can then be placed on the wafer using known methods. The advantage here is that the wafer can be measured more accurately. This in turn has the advantage that due to the more accurate measurement of the wafer, it is possible to react more specifically to process changes, e.g., with a R2R controller, and thus the wafer can be processed more reliably. As a result, fewer rejects are produced.

In a preferred embodiment, the zones C,D,E are radially defined. Alternatively, the zones can be defined as rectangles or squares on the wafer. Alternatively, the zones can be defined as ellipses.

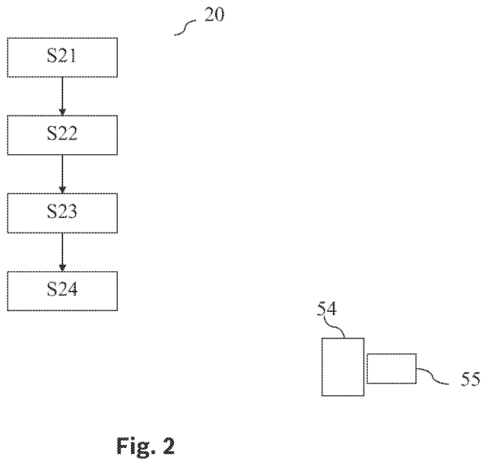

FIG. 2 schematically shows a flow chart of a method for creating a measurement pattern of measurement points (24) for a semiconductor wafer (23).

The method begins with obtaining (S21) a plurality of measured values and their associated measurement points and associated timestamps. This is followed by a partitioning (S22) of the semiconductor wafer (23) into a plurality of zones (C,D,E), wherein measured values whose measurement positions are within the respective zone (C,D,E) have substantially the same characteristic. This is followed by a determination (S23) for each of the zones (C,D,E) of a variation along a predetermined time period of those measured values whose timestamps are within a predetermined time window. This is followed by a definition (S24) of the measurement pattern, wherein a measurement point density is defined for each of the zones (C,D,E) depending on the determined variations.

Optionally, a freshly produced wafer can be measured according to the measurement pattern.

The method can be implemented as a computer program stored on a machine-readable storage medium 54 and can be executed by a processor 55. The term “computer” includes any device for processing specifiable calculation rules. These calculation rules can be provided in the form of software or in the form of hardware or also in a mixed form of software and hardware.

What is claimed is:

1. A method for optimizing a measurement pattern of measurement points for a semiconductor wafer, comprising:
obtaining a plurality of measured values with associated measurement points and timestamps;
partitioning the semiconductor wafer into a plurality of zones, wherein measured values whose measurement positions are within the respective zone have substantially the same characteristic;
determining, for each of the zones, a variation along a predetermined time period of those measured values whose timestamps are within a predetermined time window; and
defining the measurement pattern, wherein a measurement point density is defined for each of the zones depending on the determined variations.

2. The method of claim 1, wherein:
a predetermined maximum number of measurement points is predetermined, and
the predetermined number of measurement points is distributed on the wafer according to the measurement pattern.

3. The method of claim 1, wherein the zones are each associated with a surface portion of the semiconductor wafer.

4. The method according to claim 1, wherein the variations are determined with a measure of dispersion.

5. An apparatus which is configured to carry out the method according to claim 1.

6. A computer program comprising instructions which, when the program is performed by a computer, cause the computer to carry out the method according to claim 1.

7. A machine-readable storage medium on which the computer program according to claim 6 is stored.

8. The method according to claim 1, wherein the variations are determined with a standard deviation.
